(19) United States
(12) Patent Application Publication
(10) Pub. No.: US 2012/0206379 A1
(43) Pub. Date: Aug. 16, 2012

(54) Single-layer and multi-touch projected capacitive apparatus

(75) Inventors: Wei-Hsuan Ho, Hsinchu County (TW); Yu-Chuan Chen, Taoyuan County (TW); Yu-Cheng Lin, Pingtung County (TW)

(73) Assignee: SWENC TECHNOLOGY CO., LTD., Taoyuan County (TW)

(21) Appl. No.: 13/136,563

(22) Filed: Aug. 3, 2011

(30) Foreign Application Priority Data
Feb. 14, 2011 (TW) 100104836

(51) Int. Cl. G06F 3/041; H05K 1/00; H05K 1/11; H05K 3/00

(52) U.S. Cl. 345/173; 427/98.4; 174/250; 174/261

(57) ABSTRACT

A single-layer and multi-touch projective-capacitive apparatus includes: (a) a substrate, (b) a conductive layer configured on the substrate, wherein the conductive layer consists of a plurality of first patterns, a plurality of second patterns, a plurality of third patterns and a plurality of fourth patterns, and (c) a plurality of conductive wires configured on the substrate respectively to connect with the first patterns, the second patterns, the third patterns and the fourth patterns.

### FIELD OF THE INVENTION

The present invention relates to a single-layer and multi-touch projected capacitive apparatus, in particular to a single-layer and multi-touch projected capacitive touch panel.

### BACKGROUND OF THE INVENTION

The projected capacitive touch panel having multi-touch function has been the focus of touch panel since the iPhone becomes available in the market. The specialist are directed to develop capacitive apparatus with light in weight, thin and small in size following as the market development, in particular how to upgrade the sensitivity of multi-touch and writing perception of single-layer capacitive touch panel has become a working objective of relevant industries. The relevant technology well known can be referred to China invention patent application number: 098204703.

It is known from the above-mentioned patent that the capacitive touch panel apparatus includes a substrate. Please refer to FIG. 1A and FIG. 1B, which are the structure drawings of the known capacitive touch panel apparatus. On the substrate 1, a plurality of first electrodes 2 and a plurality of second electrodes 3 are in alternative arrangement, and every the first electrode 2 extended from the top 211 to the electrode forming area 21 on the bottom 212 of the substrate has further extension with the first conducting wire 31. A plurality of second electrodes 3 are in ordered array, wherein each column of the second electrodes 3 are located between the two neighboring first electrodes 2, and a channel 4 between the first and second electrodes is defined; then a plurality of second conducting wires 32 which are extended from the same column of a plurality of second electrodes 3 are alternately falling in the two channels 4 in neighboring to the column. In the same time, the second conducting wires 32 are also situated on the electrode forming area 21. Each of first electrodes 2 and each of second electrodes 3, wherein both are located in the same column are forming a capacitive induction unit 5. The plurality of second electrodes 2 in the same column are different is size, and for those second electrodes 2 which are closer to the bottom 212 are getting smaller than the others. Each of the first and the second electrodes 2, 3 are rectangular in structure. The defect of above capacitive touch panel apparatus is that the graphic structure is complex and the sensitivity (especial for oblique sensitivity) of multi-touch is poor.

Hence, the purpose of the invention promptly provides electrode graphics of the projected capacitive touch panel, wherein the graphics is simple in structure and has excellent sensitivity to be effectively reducing the manufacturing cost.

### SUMMARY OF THE INVENTION

According to above concept, an invention for providing single-layer multi-touch projected capacitive touch apparatus is provided that includes a substrate, a conductive layer which is implemented on the substrate and has a plurality of first patterns, a plurality of second patterns, a plurality of third patterns and a plurality of fourth patterns. As well as, the apparatus also contains a plurality of conducting wires which are connected individually to the first pattern, the second pattern, the third pattern and the fourth pattern, while the first patterns, the second patterns, the third patterns, the fourth patterns and the conducting wires are not to get in touch with each other.

Preferably, the present invention provides the said touch panel, wherein the material of the substrate is transparent.

Preferably, the present invention provides the said touch panel, wherein the material of the conductive layer is transparent conductive material.

Preferably, the present invention provides the said touch panel, wherein the first pattern, the second pattern, the third pattern and the fourth pattern are triangle, and then the first pattern and the second pattern are complementary in configuration, and both are forming the fifth pattern, wherein a first line is formed in the complementary position. The third pattern and the fourth pattern are complementary in configuration, and both are forming the sixth pattern, wherein a second line is formed in the complementary position.

Preferably, the present invention provides the said touch panel, wherein the first line of the fifth pattern is diagonal symmetry in arrangement with the second line of the sixth pattern.

Preferably, the present invention provides the said touch panel, further including a plurality of conducting wires, wherein each of the conducting wires is electrically connected to the first pattern, the second patter, the third pattern and the fourth pattern, separately.

According to above concept, an invention for providing the manufacturing method of single-layer multi-touch projected capacitive touch panel is provided, including: (a) providing a substrate; and (b) forming a conductive layer on the substrate, and the conductive layer has a plurality of first patterns, a plurality of second patterns, a plurality of third patterns and a plurality of fourth patterns and a plurality of conducting wires, wherein they are insulated mutually. And each of the conducting wires is electrically connected to the first pattern, the second patter, the third pattern and the fourth pattern to be used to output a plurality of inducing signals from the first pattern, the second pattern, the third pattern and the fourth pattern.

Preferably, the present invention provides the manufacturing method, wherein the step (a) further includes: (a1) providing a substrate which has transparent conductive material.

Preferably, the present invention provides the manufacturing method, wherein the step (b) further includes: (b1) implementing a lithography process on the substrate to form a plurality of electrode patterns of the conductive layer, wherein the first pattern, the second pattern, the third pattern and the fourth pattern are triangle, and they are connected to the conducting wires individually with mutually insulated. Moreover, the first, the second, the third and the fourth patterns are but not limited to four triangles. They can be any complementary in relation with geometry, such as polygon and patterns having not specific sidelines

The present invention may best be understood through the following descriptions with reference to the accompanying drawings, in which:

### BRIEF DESCRIPTION OF THE DRAWINGS

FIGS. 1A and 1B are diagrams of convention structure of the projected capacitive touch panel;

FIG. 2 is a diagram of manufacturing method flow chart of the projected capacitive touch panel;

FIG. 3 is a diagram illustrating a hierarchical schematic corresponding to the manufacturing method of projected capacitive touch panel in FIG. 2;

FIG. 4A is a diagram illustrating the structure of projected capacitive touch panel of the first embodiment corresponding to FIG. 3;

FIG. 4B is a diagram illustrating the structure of projected capacitive touch panel of the second embodiment corresponding to FIG. 3; and

FIG. 4C is a diagram illustrating the structure of projected capacitive touch panel of the third embodiment corresponding to FIG. 3.

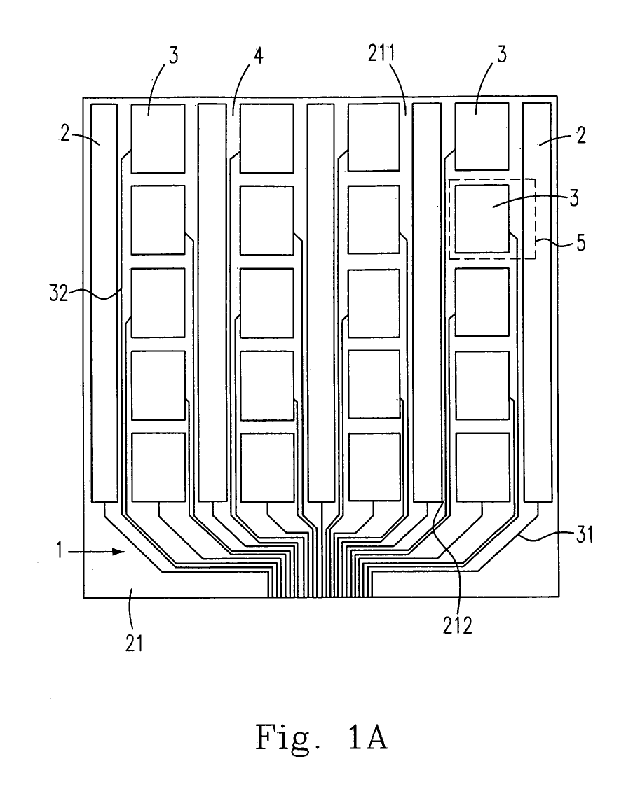

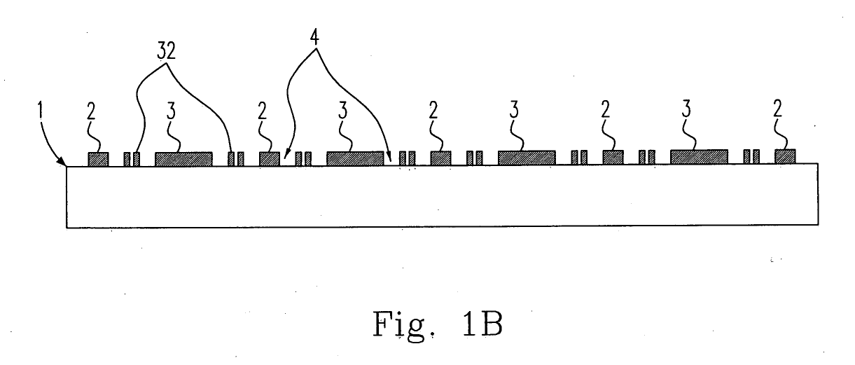

### DETAILED DESCRIPTION OF THE PREFERRED EMBODIMENT

The present invention will now be described more specifically with reference to the following embodiments. It is to be noted that the following descriptions of preferred embodiments of this invention are presented herein for purposes of illustration and description only; it is not intended to be exhaustive or to be limited to the precise form disclosed.

The present invention discloses the flow chart diagram of manufacturing method of the projected capacitive touch panel. This manufacturing method 200 includes following steps:

Step 201: providing a substrate having a transparent conductive material, wherein the preferred material of the substrate is transparent.

Step 202: implementing a lithography process on the substrate.

Finally, a patterned conductive layer having a plurality of first patterns, a plurality of second patterns, a plurality of third patterns, a plurality of fourth patterns and a plurality of conducting wires is formed.

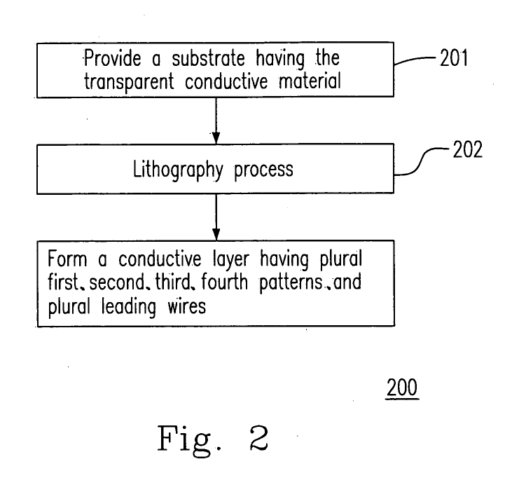

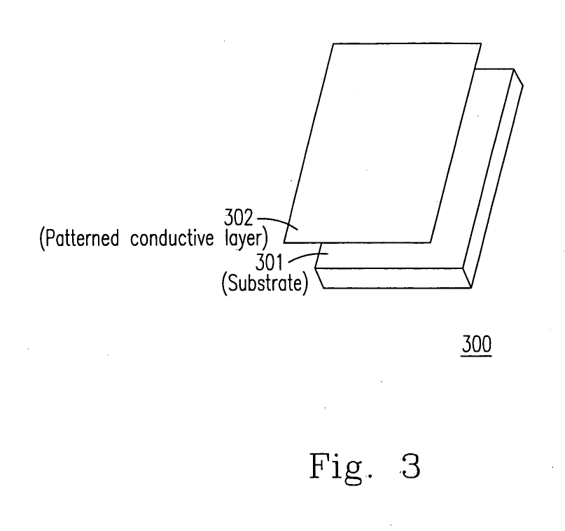

FIG. 3 is a diagram showing a hierarchical schematic corresponding to the manufacturing method of projected capacitive touch panel in FIG. 2. The illustration of hierarchical schematic in FIG. 3 can be referred to FIG. 2. In FIG. 3, a single-layer multi-touch projected capacitive touch panel 300 is stratified to substrate 301 and patterned conductive layer 302.

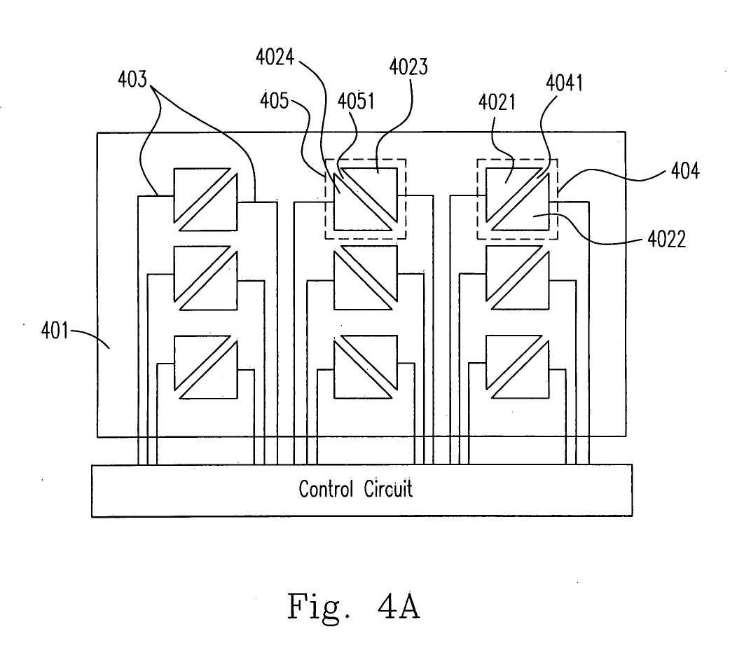

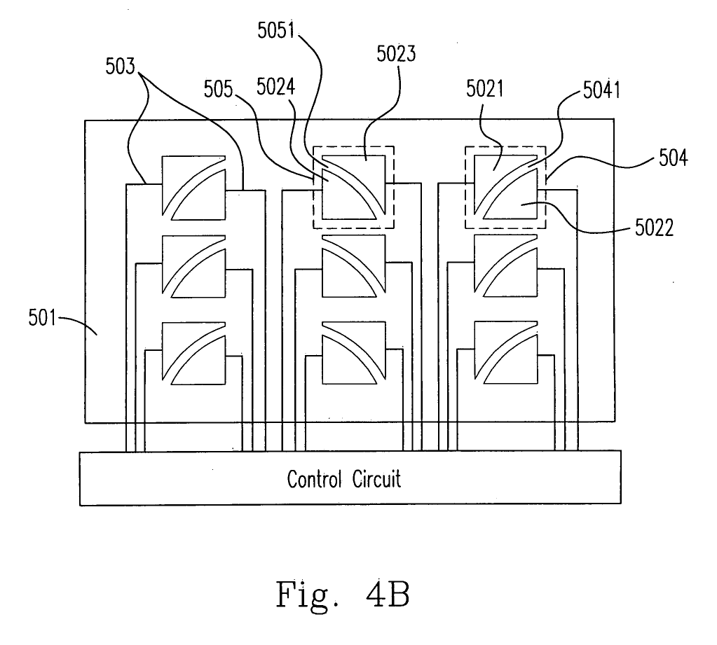

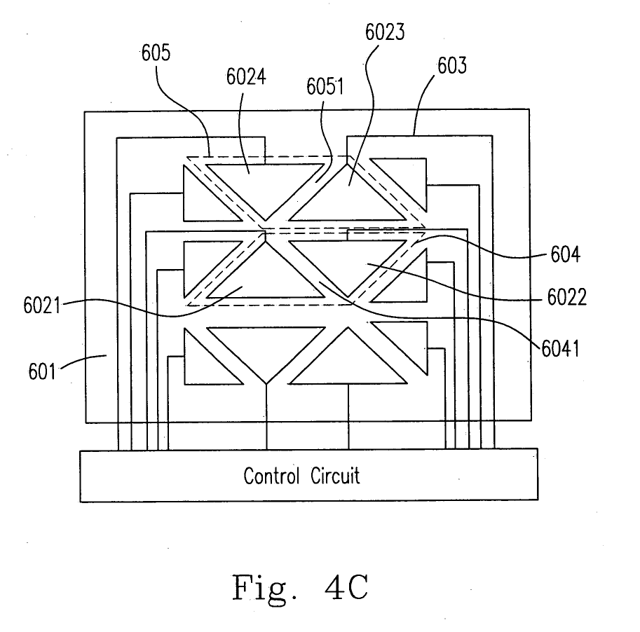

FIG. 4A is a diagram showing the structure of projected capacitive touch panel of the better embodiment corresponding to FIG. 3. The structure schematic in FIG. 4A can be referred to FIG. 3. In FIG. 4A, a plurality of first patterns 4021, a plurality of second patterns 4022, a plurality of third patterns 4023, a plurality of fourth patterns 4024 and a plurality of conducting wires 403 are forming graphics and the patterned conductive layer is to come into being on the substrate 401, wherein the patterned conductive layer including a plurality of first patterns 4021, a plurality of second patterns 4022, a plurality of third patterns 4023, a plurality of fourth patterns 4024 and a plurality of conducting wires 403, and then a plurality of patterns are keeping mutually insulated, while the material of the substrate 301 and conductive layer 302 are better of transparent conductive material, as the first pattern 4021 and the second pattern 4022 are complementary in configuration, and both are forming the fifth pattern 404, wherein a first line 4041 is formed in the complementary position. The third pattern 4023 and the fourth pattern 4024 are complementary in configuration, and both are forming the sixth pattern 405, wherein a second line 4051 is formed in the complementary position. In FIG. 4A, although the first line 4041 and the second line 4051 are forming straight lines from two patterns which are complementary in configuration, but for those people who are skilled in the art can design two patterns having special complementary with necessity, and the first line and the second line can be designed as curves as shown in FIG. 4B. In the other hands, the first line and the second line are the vacant spaces between two complementary patterns in microcosmic, however the first line and second line can be viewed as a line of two complementary patterns in micro, and the first line 4041 and the second line 4051 are diagonal symmetry in arrangement. Furthermore, the conducting wires are individually connected to the first, the second, the third and the fourth patterns to form single electrode pattern which has conducting wires for unitary controlling the signal, hence a multi-touch induction is reached. In this embodiment, the first, the second, the third and the fourth patterns are limited to being four triangle patterns in the x-axis direction of FIG. 4A and FIG. 4B; but can be modified to being not limited to four triangle patterns in the x-axis direction such as FIG. 4C. In FIG. 4C, the first pattern 6021 and the second pattern 6022 are complementary in configuration, and both are forming the fifth pattern 604, wherein a first line 6041 is formed in the complementary position. The third pattern 6023 and the fourth pattern 6024 are complementary in configuration, and both are forming the sixth pattern 605, wherein a second line 6051 is formed in the complementary position. The first line 6041 and the second line 6051 are forming straight lines from two patterns which are complementary in configuration, and are diagonal symmetry in arrangement. Moreover, the first, the second, the third and the fourth patterns are but not limited to four triangles, and those patterns which are complementary in relation with geometry such as polygon and patterns having not specific sidelines can be implemented in present invention. The above description has been clearly explaining the structure of better embodiment and the present invention can be implemented by those workers who are skilled in the art.

In summary, the embodiment of above mentioned invention has provided the single-layer multi-touch projected capacitive touch panel. Due to the patterned conductive layer and a plurality of conducting wires are constructed with one time coating but not performing two coatings for x-axis patterned conductive layer and y-axis patterned conductive layer separately, thus consistent color film is guaranteed without resulting of apparent triangle pattern. Furthermore, the present invention is a single layer structure, which can reduce the barrier to the light and raise the surface light transmittance of the touch panel. What is more, through the design of present invention, the electrode units of a plurality of first patterns, a plurality of second patterns, a plurality of third patterns and a plurality of fourth patterns within the structure of electrode patterns are implemented on the same plane surface of the substrate, and having the effect of on simple structure and reducing the thickness and weight of structure. For industrial usage as well, the production of each electrode unit and conducting wire in the electrode patterned structure can be implemented on single surface on the substrate by using simplified lithography process once to finish the needed electrode patterned structure of touch panel, thus this confirms the superiority of simple process, high yield and low manufacturing cost. Besides, the electric fields of the electrode unit which are under the touched position will be changed by user grope, hence this phenomenon will cause change of capacitance between the first, the second, the third and the fourth electrodes of the electrode unit, and allow the control unit to detect the coordinate of the position touched by the user. Furthermore, the creative work of present invention has four patterns which are triangle electrode patterns, that each of the first pattern and each of the second pattern are complementary in configuration to form the fifth pattern 604, wherein a first line 6041 is formed in the complementary position, and each of the third pattern and each of the fourth pattern are complementary in configuration to form the sixth pattern, wherein a second line is formed in the complementary position, while the first line of the fifth pattern and the second line of the sixth pattern are diagonal symmetry in arrangement. This configuration compared to the known configuration mode of square electrode pattern has better sense of oblique writing and sensitivity. In summary, the above mentioned method has greatly elevated the writing recognition and touching sensitivity, hence the present invention is patentable.

While the invention has been described in terms of what are presently considered to be the most practical and preferred embodiments, it is to be understood that the invention need not be limited to the disclosed embodiment. On the contrary, it is intended to cover various modifications and similar arrangements included within the spirit and scope of the appended claims, which are to be accorded with the broadest interpretation so as to encompass all such modifications and similar structures. Therefore, the above description and illustration should not be taken as limiting the scope of the present invention which is defined by the appended claims.

What is claimed is:

1. A touch panel, comprising:
a substrate;
a conductive layer implemented on the substrate and having a first, a second, a third and a fourth patterns insulated from one another; and
a plurality of leading wires electrically connected to the first, the second, the third and the fourth patterns respectively and used to output a plurality of induced signals.

2. The touch panel according to claim 1, wherein the substrate is transparent, and the conductive layer is made of a transparent conductive material.

3. The touch panel according to claim 1, wherein the first and the second patterns are complementary in configuration to form a fifth pattern, and the third and the fourth patterns are complementary in configuration to form a sixth pattern.

4. The touch panel according to claim 3, wherein the first pattern neighbors with the second pattern and the fifth pattern has a first line formed between the first and the second patterns, and the third pattern neighbors with the fourth pattern and the sixth pattern has a second line formed between the third and the fourth patterns.

5. The touch panel according to claim 4, wherein the first line of the fifth pattern and the second line of the sixth pattern are in a form of mirror symmetry.

6. The touch panel according to claim 1, wherein the a plurality of induced signals are from the first, the second, the third and the fourth patterns.

7. The touch panel according to claim 1, wherein each of the first, the second, the third and the fourth patterns is a triangle.

8. A manufacturing method for producing a touch panel, comprising:
(a) providing a substrate; and
(b) implementing on the substrate a conductive layer having a first, a second, a third and a fourth patterns and a plurality of leading wires, wherein the first, the second, the third and the fourth patterns are insulated from one another and the a plurality of leading wires are electrically connected to the first, the second, the third and the fourth patterns respectively so as to output a plurality of induced signals.

9. The method according to claim 8, wherein the step of (b) is performed by a lithography process on the substrate, and each of the first, the second, the third and the fourth patterns is a triangle.

10. The method according to claim 8, wherein the first and the second patterns are complementary in configuration, to form a fifth pattern and the third and the fourth patterns are complementary in configuration, to form a sixth pattern.

11. The method according to claim 10, wherein the first pattern neighbors with the second pattern and the fifth pattern has a first line formed between the first and the second patterns, and the third pattern neighbors with the fourth pattern and the sixth pattern has a second line formed between the third and the fourth patterns

12. The method according to claim 8, wherein the a plurality of induced signals are from the first, the second, the third and the fourth patterns.

13. A conductive layer, comprising:
a first pattern;
a second pattern complementary to the first pattern;
a third pattern; and
a fourth pattern complementary to the third pattern.

14. The conductive layer according to claim 13 further comprising a plurality of leading wires electrically connected to the first, the second, the third and the fourth patterns respectively.

15. The conductive layer according to claim 13 implemented in a touch panel.
